(19) United States
(12) Patent Application Publication
(10) Pub. No.: US 2017/0053859 A1
(43) Pub. Date: Feb. 23, 2017

(54) ELECTRONIC PACKAGE AND FABRICATION METHOD THEREOF

(71) Applicant: Siliconware Precision Industries Co., Ltd., Taichung (TW)

(72) Inventors: Fang-Yu Liang, Taichung (TW); Hung-Hsien Chang, Taichung (TW); Yi-Che Lai, Taichung (TW)

(21) Appl. No.: 14/982,099

(22) Filed: Dec. 29, 2015

(30) Foreign Application Priority Data
Aug. 20, 2015 (TW) 104127127

(51) Int. Cl. H01L 23/498; H01L 21/78; H01L 21/56; H01L 23/31; H01L 23/053

(52) U.S. Cl. CPC H01L 23/49838; H01L 23/49827; H01L 23/3121; H01L 23/49833; H01L 23/053; H01L 21/561; H01L 21/78

(57) ABSTRACT

A method for fabricating an electronic package is provided, including the steps of: providing an interposer having a plurality of conductive vias and at least an opening formed at a periphery of the conductive vias; disposing at least an electronic element on the interposer; and bonding a cover plate to the electronic element and forming an encapsulant between the cover plate and the interposer so as to encapsulate the electronic element and fill the opening, thus allowing the encapsulant in the opening to come into contact with air. As such, during a subsequent high temperature process, evaporated solvents can flow out of the encapsulant through the opening without forming bubbles in the encapsulant, thereby preventing a bubble explosion from occurring. The invention further provides an electronic package.

### BACKGROUND OF THE INVENTION

1. Field of the Invention

The present invention relates to packaging processes, and more particularly, to an electronic package and a fabrication method thereof for improving the process reliability.

2. Description of Related Art

Along with the rapid development of electronic industries, electronic products are developed toward the trend of multi-function and high performance. Accordingly, there have been developed various types of flip-chip packaging modules such as chip scale packages (CSPs), direct chip attached (DCA) packages and multi-chip modules (MCM), and 3D IC chip stacking technologies.

FIGS. 1A and 1B are schematic cross-sectional views showing a method for fabricating a semiconductor package 1 according to the prior art.

Referring to FIG. 1A, a cover plate 12 and a silicon interposer 10 having a plurality of through silicon vias (TSVs) and redistribution layers are provided. By performing a chip on wafer (CoW) process, a plurality of semiconductor chips 11 are disposed on the silicon interposer 10 through a plurality of conductive bumps 110.

Referring to FIG. 1B, the cover plate 12 is laminated on the silicon interposer 10. Then, a molding process is performed to form an encapsulant 13 between the cover plate 12 and the silicon interposer 10 for encapsulating the semiconductor chips 13. In particular, since the semiconductor chips 11 are quite thin in thickness, the cover plate 12 is disposed on the semiconductor chips 11 before formation of the encapsulant 13 so as to support and secure the semiconductor chips 11.

Current molding technologies can effectively reduce formation of voids during flow of the molding compounding of the encapsulant 13.

Further, after the molding process, a high temperature process is often performed at a temperature higher than 200° C. For example, through the high temperature process, a plurality of solder balls are formed on a lower side of the silicon interposer 10 and then reflowed to bond with an electronic device.

However, the encapsulant 13 contains not only an epoxy resin but also various solvents such as a hardening agent, a filler, a catalyst and a release agent. At a temperature higher than 200° C., the solvents will be decomposed into gases. Since upper and lower sides of the encapsulant 13 are covered by the cover plate 12 and the silicon interposer 10, respectively, the gases cannot flow out. Instead, the gases remain in the encapsulant 13 to form bubbles. As such, when another high temperature process such as a SMT (surface mounting technology) process is performed, the bubbles easily expand and explode, thereby reducing the product reliability.

Therefore, how to overcome the above-described drawbacks has become critical.

### SUMMARY OF THE INVENTION

In view of the above-described drawbacks, the present invention provides an electronic package, which comprises: an interposer having opposite first and second surfaces and at least a side surface adjacent to and connecting the first and second surfaces, wherein a plurality of conductive vias are formed in the interposer and communicating the first and second surfaces of the interposer, and at least an opening is formed along the side surface of the interposer; at least an electronic element disposed on the first surface of the interposer; and an encapsulant formed on the first surface of the interposer so as to encapsulate the electronic element and fill the opening.

In the above-described package, a redistribution layer can be formed on the first surface of the interposer and electrically connected to the electronic element.

In the above-described package, a redistribution layer can be formed on the first or second surface of the interposer and electrically connected to the conductive vias.

In the above-described package, the opening can be formed at an interface between the first surface and the side surface of the interposer.

In the above-described package, the encapsulant can be made of a molding compound or a dielectric material.

In the above-described package, the electronic element can be exposed from a surface of the encapsulant.

The above-described package can further comprise a cover plate bonded to the electronic element in a manner that the encapsulant is formed between the first surface of the interposer and the cover plate.

The above-described package can further comprise a plurality of conductive elements formed on the second surface of the interposer and electrically connected to the interposer.

The above-described package can further comprise a packaging substrate bonded to the second surface of the interposer and electrically connected to the interposer.

The present invention further provides a method for fabricating an electronic package, which comprises the steps of: providing an interposer having a plurality of conductive vias and at least an opening formed at a periphery of the conductive vias; disposing at least an electronic element on a first surface of the interposer; and bonding a cover plate to the electronic element and forming an encapsulant between the cover plate and the first surface of the interposer so as to encapsulate the electronic element and fill the opening.

In the above-described method, the interposer can have a redistribution layer electrically connected to the electronic element.

In the above-described method, the interposer can have a redistribution layer electrically connected to the conductive vias.

In the above-described method, the opening can be formed by mechanical processing, laser processing or etching.

After forming the encapsulant, the above-described method can further comprise performing a singulation process along the opening.

In the above-described method, the encapsulant can be formed by molding or laminating.

After forming the encapsulant, the above-described method can further comprise removing the cover plate so as to expose the electronic element from a surface of the encapsulant.

After forming the encapsulant, the above-described method can further comprise performing a singulation process along the opening.

After forming the encapsulant, the above-described method can further comprise forming a plurality of conductive elements on a second surface of the interposer opposite to the first surface, wherein the conductive elements are electrically connected to the interposer.

After forming the encapsulant, the above-described method can further comprise bonding a packaging substrate to a second surface of the interposer opposite to the first surface, wherein the packaging substrate is electrically connected to the interposer.

According to the present invention, at least an opening is formed in the interposer so as to allow the encapsulant filled in the opening to be exposed from the interposer and come into contact with air. As such, in a subsequent high temperature process, evaporated solvents in the encapsulant can flow out of the encapsulant through the opening without forming bubbles in the encapsulant, thereby preventing a bubble explosion from occurring.

### BRIEF DESCRIPTION OF DRAWINGS

FIGS. 1A and 1B are schematic perspective and cross-sectional views showing a method for fabricating a semiconductor package according to the prior art; and

FIGS. 2A to 2F are schematic cross-sectional views showing a method for fabricating an electronic package according to the present invention, wherein FIG. 2B′ is a schematic upper view of FIG. 2B, and FIGS. 2E′ and 2E″ show other embodiments of FIG. 2E.

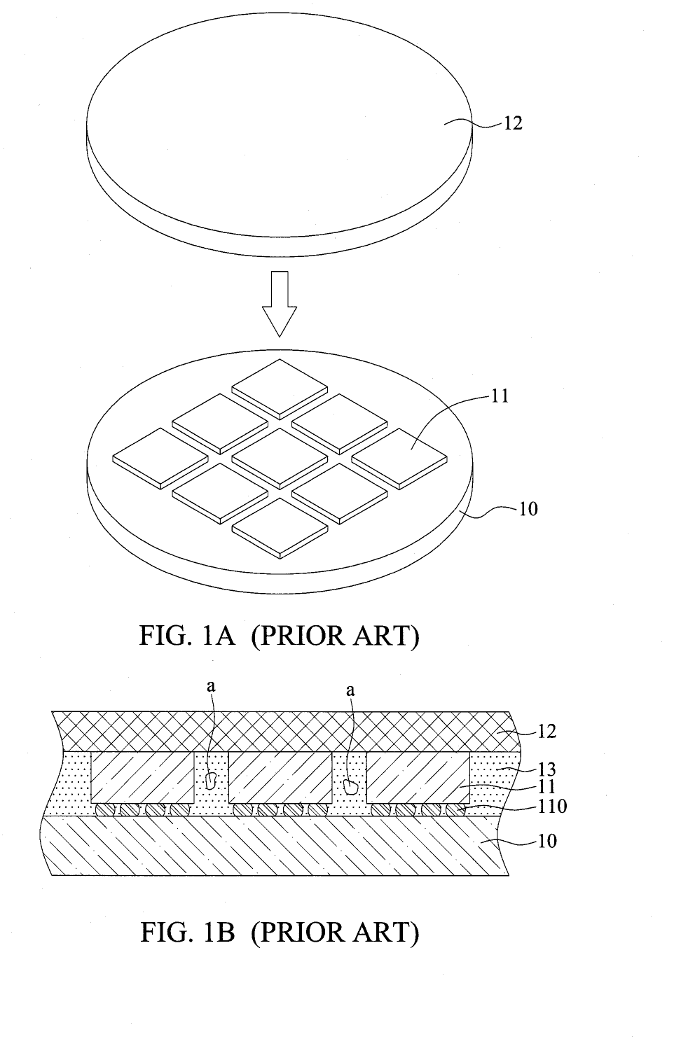

### DETAILED DESCRIPTION OF PREFERRED EMBODIMENTS

The following illustrative embodiments are provided to illustrate the disclosure of the present invention, these and other advantages and effects can be apparent to those in the art after reading this specification.

It should be noted that all the drawings are not intended to limit the present invention. Various modifications and variations can be made without departing from the spirit of the present invention. Further, terms such as “first”, “second”, “on”, “a” etc. are merely for illustrative purposes and should not be construed to limit the scope of the present invention.

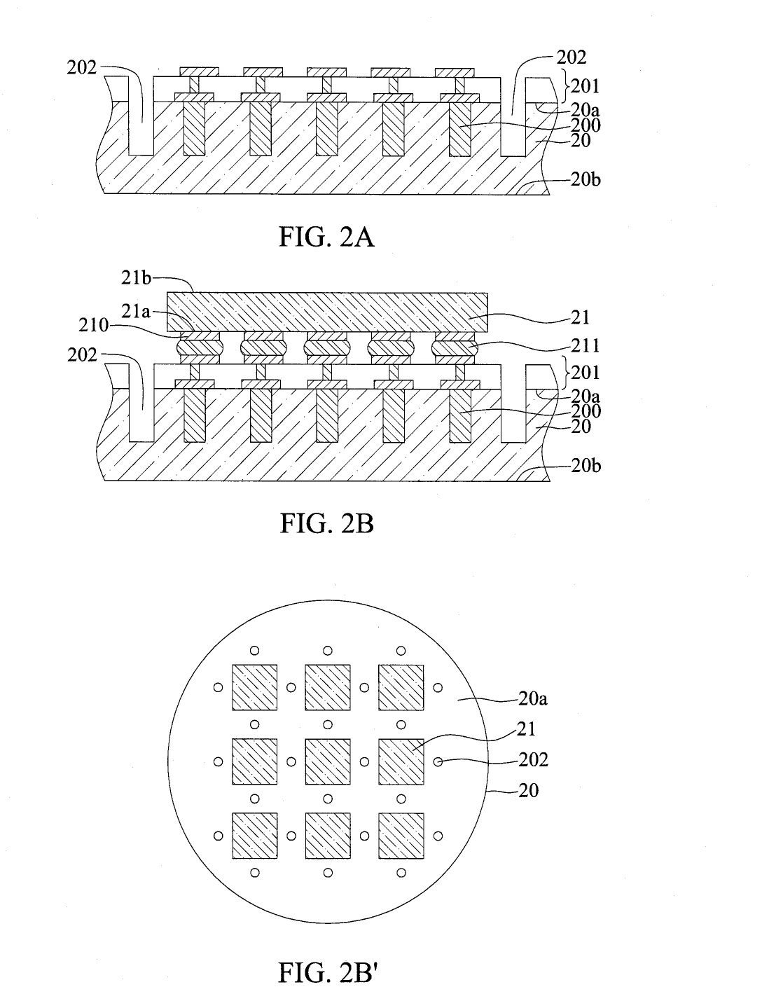

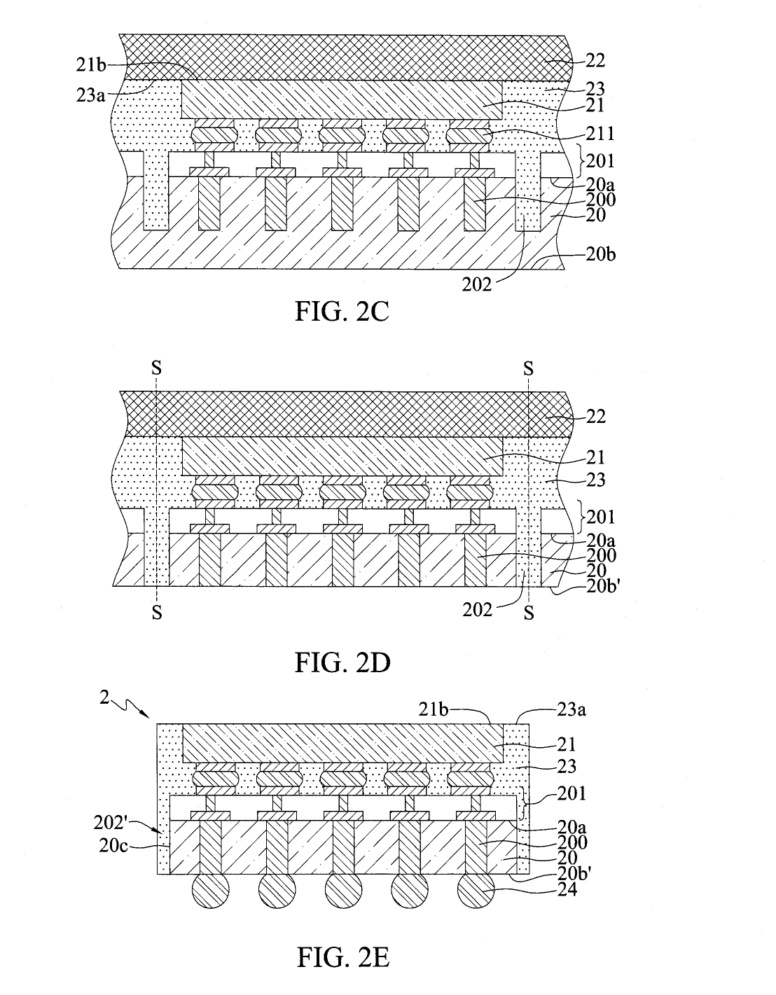

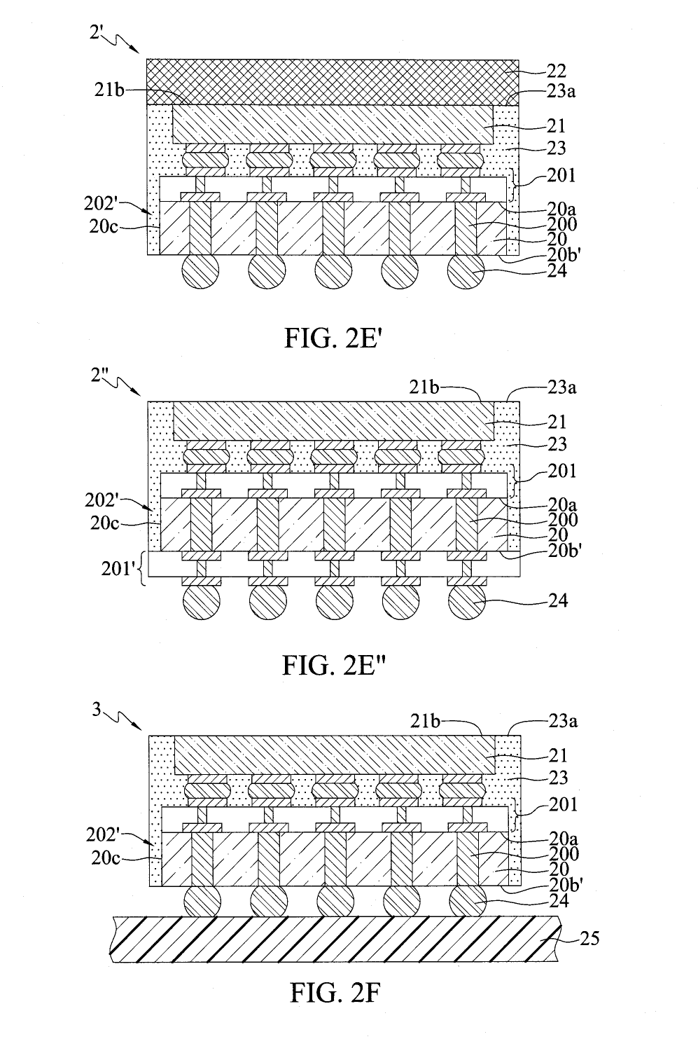

FIGS. 2A to 2F are schematic cross-sectional views showing a method for fabricating an electronic package 2, 2′, 2″, 3 according to the present invention.

Referring to FIG. 2A, an interposer 20 having a plurality of conductive vias 200 is provided. The interposer 20 has a first surface 20a and a second surface 20b opposite to the first surface 20a, and the conductive vias 200 communicate with the first surface 20a of the interposer 20. Further, a plurality of openings 202 are formed on the first surface 20a of the interposer 20 at a periphery of the conductive vias 200.

In the present embodiment, a redistribution layer 201 is formed on the first surface 20a of the interposer 20 and electrically connected to the conductive vias 200.

The openings 202 are formed by mechanical processing such as drilling, sawing or milling, laser processing or etching.

Referring to FIGS. 2B and 2B′, a plurality of electronic elements 21 are disposed on the first surface 20a of the interposer 20.

In the present embodiment, each of the electronic elements 21 is an active element such as a semiconductor chip, a passive element such as a resistor, a capacitor or an inductor, or a combination thereof.

The electronic element 21 is disposed on the redistribution layer 201 in a flip-chip manner. In particular, the electronic element 21 has an active surface 21a with a plurality of electrode pads 210 and an inactive surface 21b opposite to the active surface 21a. The electrode pads 210 of the electronic element 21 are bonded to the redistribution layer 201 through a plurality of conductive bumps 211.

Referring to FIG. 2B′, the electronic elements 21 do not cover the openings 202.

Referring to FIG. 2C, a cover plate 22 is bonded to the inactive surfaces 21b of the electronic elements 21, and an encapsulant 23 is formed between the cover plate 22 and the first surface 20a of the interposer 20 so as to encapsulate the electronic elements 21 and the conductive bumps 211. The encapsulant 23 is further filled in the openings 202.

In the present embodiment, the encapsulant 23 is formed by molding or laminating and made of a molding compound or a dielectric material. In particular, to perform a molding process, the cover plate 22 is bonded to the electronic elements 21 first and then the encapsulant 23 made of such as an epoxy resin is formed between the cover plate 22 and the first surface 20a of the interposer 20.

To perform a laminating process, a dielectric material such as ABF (Ajinomoto Build-up Film) or prepreg is first attached to the electronic elements 21 by dispensing and then the cover plate 22 is laminated on the dielectric material. Alternatively, the dielectric material is coated on the cover plate 22 first and then the cover plate 22 with the dielectric material facing the electronic elements 21 is laminated on the interposer 20.

Further, the inactive surfaces 21b of the electronic elements 21 are flush with an upper surface 23a of the encapsulant 23.

Referring to FIG. 2D, the interposer 20 is partially removed from the second surface 20b thereof so as to form a second surface 20b′, and the conductive vias 200 and the openings 202 communicate with the second surface 20b′ of the interposer 20.

In the present embodiment, a planarization process, such as grinding, is performed to cause one ends of the conductive vias 200 and the openings 202 to be flush with the second surface 20b′ of the interposer 20. As such, the encapsulant 23 in the openings 202 is exposed from the second surface 20b′ of the interposer 20.

Referring to FIG. 2E, a singulation process is performed along the openings 202 (i.e., along cutting paths S of FIG. 2D), thus forming openings 202′ along side surfaces 20c of the interposer 20. Further, a plurality of conductive elements 24 are formed on the second surface 20b′ of the interposer 20.

In the present embodiment, the cover plate 22 is removed to expose the inactive surfaces 21b of the electronic elements 21 from the upper surface 23a of the encapsulant 23. Alternatively, in another embodiment, referring to FIG. 2E′, the cover plate 22 is not removed.

Further, the conductive elements 24 are electrically connected to the conductive vias 200. The conductive elements 24 are solder balls, metal bumps or the like.

The openings 202′ communicate the first surface 20a and the second surface 20b′ of the interposer 20.

Furthermore, the encapsulant 23 can be formed on the side surfaces 20c of the interposer 20.

In another embodiment, referring to FIG. 2E″, a redistribution layer 201′ is formed on the second surface 20b′ of the interposer 20 and electrically connected to the conductive vias 200, and the conductive elements 24 are formed on the redistribution layer 201′.

Referring to FIG. 2F, the interposer 20 is bonded to a packaging substrate 25 through the conductive elements 24.

In the present embodiment, the packaging substrate 25 has a plurality of circuit layers (not shown) electrically connected to the conductive elements 24.

According to the present invention, at least an opening 202 is formed in the interposer 20 and the interposer 20 is partially removed from the second surface 20b thereof to form a second surface 20b′ and the opening 202 communicates with the second surface 20b′ of the interposer 20. As such, the encapsulant 23 filled in the opening 202 is exposed from the second surface 20b′ of the interposer 20 and comes into contact with air. Therefore, in a subsequent high temperature process, evaporated solvents in the encapsulant 23 can flow out of the encapsulant 23 through the opening 202 (or 202′) without forming bubbles in the encapsulant 23.

Since gases decomposed from polymer materials are discharged out, the present invention prevents a bubble explosion from occurring, thereby improving the product reliability.

The present invention further provides an electronic package 2, 2′, 2″, 3, which has: an interposer 20 having opposite first and second surfaces 20a. 20b′ and a plurality of side surfaces 20c adjacent to and connecting the first and second surfaces 20a, 20b′, wherein a plurality of conductive vias 200 are formed in the interposer 20 and communicating the first and second surfaces 20a, 20b′ of the interposer 20, and at least an opening 202′ is formed along each of the side surfaces 20c of the interposer 20; at least an electronic element 21 disposed on the first surface 20a of the interposer 20; and an encapsulant 23 formed on the first surface 20a of the interposer 20 so as to encapsulate the electronic element 21 and fill the opening 202′.

In an embodiment, a redistribution layer 201 is formed on the first surface 20a of the interposer 20 and electrically connected to the electronic element 21.

In an embodiment, a redistribution layer 201, 201′ is formed on the first or second surface 20a, 20b of the interposer 20 and electrically connected to the conductive vias 202.

In an embodiment, the opening 202′ is formed at an interface between the first surface 20a and the side surface 20c of the interposer 20.

In an embodiment, the encapsulant 23 is made of a molding compound or a dielectric material.

In an embodiment, an inactive surface 21b of the electronic element 21 is exposed from an upper surface 23a of the encapsulant 23.

In an embodiment, the electronic package 2′ further has a cover plate 22 bonded to the electronic element 21 in a manner that the encapsulant 23 is formed between the first surface 20a of the interposer 20 and the cover plate 22.

In an embodiment, the electronic package 2, 2′, 2″, 3 further has a plurality of conductive elements 24 formed on the second surface 20b of the interposer 20 and electrically connected to the interposer 20.

In an embodiment, the electronic package 3 further has a packaging substrate 25 bonded to the second surface 20b of the interposer 20 and electrically connected to the interposer 20.

According to the present invention, at least an opening is formed in the interposer so as to allow the encapsulant filled in the opening to be exposed from the interposer and come into contact with air. As such, in a subsequent high temperature process, evaporated solvents in the encapsulant can flow out of the encapsulant through the opening without forming bubbles in the encapsulant, thereby preventing a bubble explosion from occurring and improving the product yield.

The above-described descriptions of the detailed embodiments are only to illustrate the preferred implementation according to the present invention, and it is not to limit the scope of the present invention. Accordingly, all modifications and variations completed by those with ordinary skill in the art should fall within the scope of present invention defined by the appended claims.

What is claimed is:

1. An electronic package, comprising:
an interposer having opposite first and second surfaces and at least a side surface adjacent to and connecting the first and second surfaces, wherein a plurality of conductive vias are formed in the interposer and communicating the first and second surfaces of the interposer, and at least an opening is formed along the side surface of the interposer;
at least an electronic element disposed on the first surface of the interposer; and
an encapsulant formed on the first surface of the interposer so as to encapsulate the electronic element and fill the opening.

2. The package of claim 1, wherein a redistribution layer is formed on the first surface of the interposer and electrically connected to the electronic element.

3. The package of claim 1, wherein a redistribution layer is formed on the first or second surface of the interposer and electrically connected to the conductive vias.

4. The package of claim 1, wherein the opening is formed at an interface between the first surface and the side surface of the interposer.

5. The package of claim 1, wherein the encapsulant is made of a molding compound or a dielectric material.

6. The package of claim 1, wherein the electronic element is exposed from a surface of the encapsulant.

7. The package of claim 1, further comprising a cover plate bonded to the electronic element in a manner that the encapsulant is formed between the first surface of the interposer and the cover plate.

8. The package of claim 1, further comprising a plurality of conductive elements formed on the second surface of the interposer and electrically connected to the interposer.

9. The package of claim 1, further comprising a packaging substrate bonded to the second surface of the interposer and electrically connected to the interposer.

10. A method for fabricating an electronic package, comprising the steps of:
providing an interposer having a plurality of conductive vias and at least an opening formed at a periphery of the conductive vias;
disposing at least an electronic element on a first surface of the interposer; and
bonding a cover plate to the electronic element and forming an encapsulant between the cover plate and the first surface of the interposer so as to encapsulate the electronic element and fill the opening.

11. The method of claim 10, wherein the interposer has a redistribution layer electrically connected to the electronic element.

12. The method of claim 10, wherein the interposer has a redistribution layer electrically connected to the conductive vias.

13. The method of claim 10, wherein the opening is formed by mechanical processing, laser processing or etching.

14. The method of claim 10, wherein the encapsulant is formed by molding or laminating.

15. The method of claim 10, after forming the encapsulant, further comprising removing the cover plate.

16. The method of claim 15, wherein the electronic element is exposed from a surface of the encapsulant.

17. The method of claim 10, after forming the encapsulant, further comprising performing a singulation process along the opening.

18. The method of claim 10, after forming the encapsulant, further comprising forming a plurality of conductive elements on a second surface of the interposer opposite to the first surface, wherein the conductive elements are electrically connected to the interposer.

19. The method of claim 10, after forming the encapsulant, further comprising bonding a packaging substrate to a second surface of the interposer opposite to the first surface, wherein the packaging substrate is electrically connected to the interposer.
